(19) United States
(12) Patent Application Publication
(10) Pub. No.: US 2012/0299204 A1
(43) Pub. Date: Nov. 29, 2012

(54) OVERLAY MARK AND METHOD FOR FABRICATING THE SAME

(75) Inventor: Chui Fu Chiu, Tao-Yuan City (TW)

(73) Assignee: NANYA TECHNOLOGY CORPORATION, Kueishan (TW)

(21) Appl. No.: 13/116,585

(22) Filed: May 26, 2011

(51) Int. Cl. H01L 23/544; H01L 21/71

(52) U.S. Cl. 257/797; 438/401; 257/E23.179; 257/E21.536

(57) ABSTRACT

A method for fabricating an overlay mark, including the steps of: forming a patterned layer on a substrate, wherein the patterned layer comprises at least one mark element forming region, wherein each mark element forming region comprises two column recesses and a plurality of row recesses, and the row recesses connect the two column recesses; growing a mark material from the sidewalls of the column recesses and the row recesses so that the mark material merges in the column recesses and the row recesses; and removing the patterned layer. Consequently, an overlay mark including mark elements with high image contrast is fabricated.

### TECHNICAL FIELD

The present invention relates to an overlay mark and a method for fabricating the same, and, more particularly, to an overlay mark and a method for fabricating the same for a spacer double patterning process.

### BACKGROUND

As circuit widths become smaller with the development of the integrated circuit (IC) manufacturing process, the control of critical dimension (CD) of components becomes more important. When two different patterns are formed in two different areas of a wafer, photoresist layers in the two different areas should be formed by different exposures, so that the respective patterns can have predetermined critical dimensions. When the pitch of a pattern is less than the resolution of a single exposure, a double patterning process can be performed to meet the requirements of the pitch of the pattern.

For a well-manufactured integrated circuit product, the pattern transfer process is performed several times to transfer the circuit patterns to each non-processing layer to form the circuit device. Therefore, it is important to align the successive patterned layers to reduce the misalignment as the critical dimension of the semiconductor device becomes smaller.

An overlay mark can be used to insure the alignment precision between the successive patterned layers. That is, after the successive patterned layers are formed, a process for determining the precision of the overlay alignment can be performed by referring to the overlay marks of the successive patterned layers.

However, the traditional mark patterns are too thin and have very low image contrast relative to a background material layer. That is, it is difficult to recognize the overlay mark by referring to the fine pattern. Therefore, for the spacer double patterning process, it is difficult to use a traditional overlay mark to monitor overlay performance. Additionally, a traditional overlay mark cannot be used for overlay measurement.

In view of the above issues, the conventional overlay mark has many problems. Therefore, there is a need for a new overlay mark and a method for fabricating the same.

### SUMMARY

To solve the problems of the above-mentioned prior art, one aspect of the present invention discloses an overlay mark which is disposed on a substrate comprising a plurality of mark elements, wherein each mark element includes two column elements and a plurality of row elements, and the row elements connect the two column elements to form a plurality of holes exposing a substrate between the two column elements.

To solve the problems of the above-mentioned prior art, another aspect of the present invention discloses a method for fabricating an overlay mark, comprising the steps of: forming a patterned layer on a substrate, wherein the patterned layer comprises at least one mark element forming region, wherein each mark element forming region comprises two column recesses and a plurality of row recesses, and the row recesses connect the two column recesses; growing a mark material from the sidewalls of the column recesses and the row recesses so that the mark material merges in the column recesses and the row recesses; and removing the patterned layer.

The foregoing has outlined rather broadly the features of the present invention in order that the detailed description of the invention to follow may be better understood. Additional features of the invention will be described hereinafter and form the subject of the claims of the invention. It should be appreciated by those skilled in the art that the concept and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a top view showing a portion of a patterned layer on a substrate;

FIG. 2 is a cross-sectional side view along line 1-1 of FIG. 1 showing column recesses of the patterned layer according to one embodiment of the present invention;

FIG. 3 is a cross-sectional side view along line 2-2 of FIG. 1 showing row recesses of the patterned layer according to one embodiment of the present invention;

FIG. 4 is a top view showing a mark material growing in the patterned layer according to one embodiment of the present invention;

FIG. 5 is a cross-sectional side view along line 3-3 of FIG. 4 according to one embodiment of the present invention;

FIG. 6 is a cross-sectional side view along line 4-4 of FIG. 4 according to one embodiment of the present invention;

FIG. 7 is a top view showing a portion of an overlay mark according to one embodiment of the present invention;

FIG. 8 is a cross-sectional side view along line 5-5 of FIG. 7 according to one embodiment of the present invention;

FIG. 9 is a cross-sectional side view along line 6-6 of FIG. 7 according to one embodiment of the present invention;

FIG. 10 is a top view showing a substrate with a plurality of device regions thereon;

FIG. 11 is a close-up top view showing an overlay mark in an overlay alignment region of the substrate according to one embodiment of the present invention; and

FIGS. 12 to 14 are schematic views showing various arrangements of mark elements according to one embodiment of the present invention.

### DETAILED DESCRIPTION

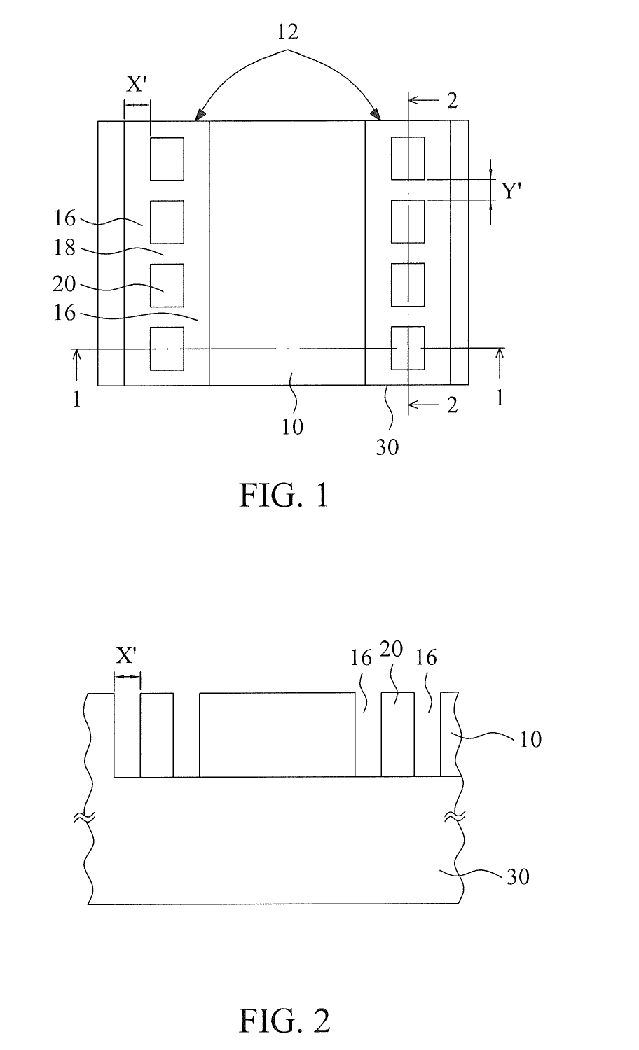

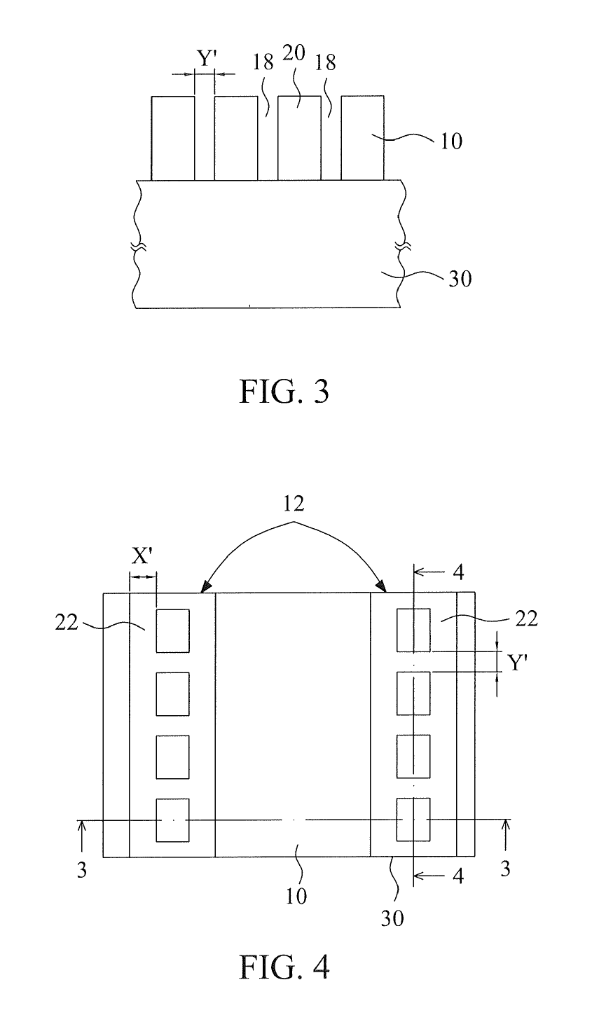

FIGS. 1 to 9 are schematic views showing a method of forming an overlay mark according to one embodiment of the present invention. FIG. 1 is a top view showing a portion of a patterned layer on a substrate. FIG. 2 is a cross-sectional side view along line 1-1 of FIG. 1 showing column recesses of the patterned layer according to one embodiment of the present invention. FIG. 3 is a cross-sectional side view along line 2-2 of FIG. 1 showing row recesses of the patterned layer according to one embodiment of the present invention.

As shown in FIGS. 1 to 3, a patterned layer 10 is formed on a silicon substrate 30 such as a wafer. The patterned layer 10 may be a photoresist layer and comprises at least one mark element forming region 12. In this embodiment, each mark element forming region 12 comprises two column recesses 16 and a plurality of row recesses 18, and the row recesses 18 connect the two column recesses 16.

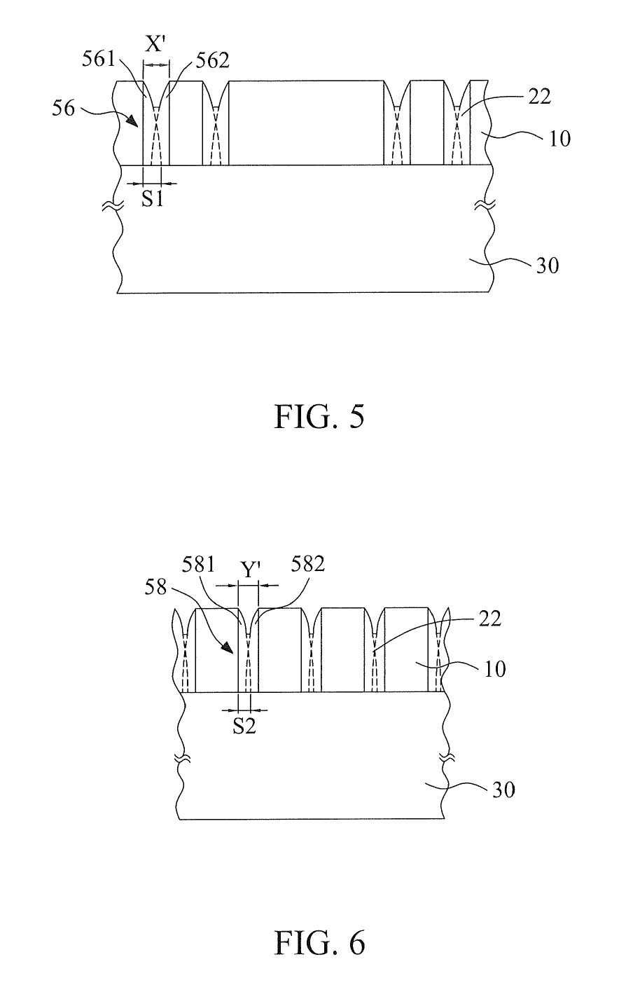

Each column recess 16 has a width X′ less than twice the width Si of a first spacer 561 or 562 (predetermined by the user) (see FIG. 5), and each row recess has a width Y′ less than twice the width S2 of a second spacer 581 or 582 (predetermined by the user) (see FIG. 6). It should be noted that the second spacer width S2 may be the same as or different from the first spacer width S1.

In this embodiment, each mark element forming region 12 further comprises a plurality of segments 20 arranged between the column recesses 16 and the row recesses 18 and spaced from each other. The segments 20 may be, but are not limited to, polygonal or circular shapes, or a combination thereof.

FIG. 4 is a top view showing a mark material growing in the patterned layer according to one embodiment of the present invention. FIG. 5 is a to cross-sectional side view along line 3-3 of FIG. 4 according to one embodiment of the present invention. FIG. 6 is a cross-sectional side view along line 4-4 of FIG. 4 according to one embodiment of the present invention. As shown in FIGS. 4 to 6, a mark material 22 grows from the sidewalls of the column recesses 16 and the row recesses 18 to form the mark material 22 merging in the column recesses 16 and the row recesses 18. In one embodiment of the present invention, the mark material 22 is made of silicon germanium (SiGe), silicon oxide, or silicon nitride. In addition to the aforementioned materials, other suitable materials for making the mark material 22 are applicable. In one embodiment of the present invention, the mark material 22 is preferably formed by low temperature chemical vapor deposition (LTCVD).

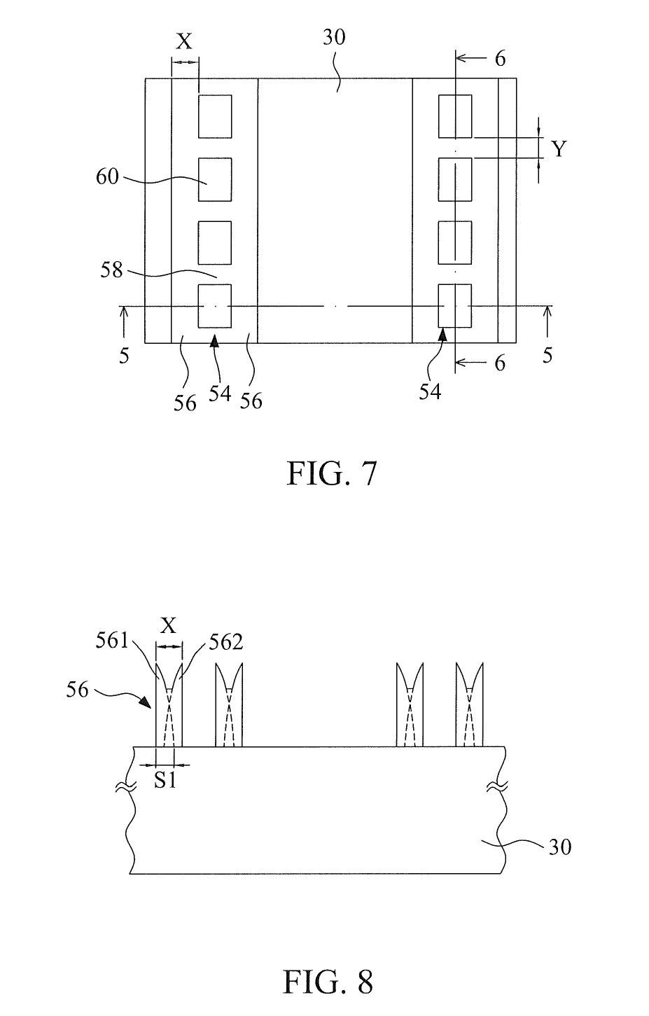

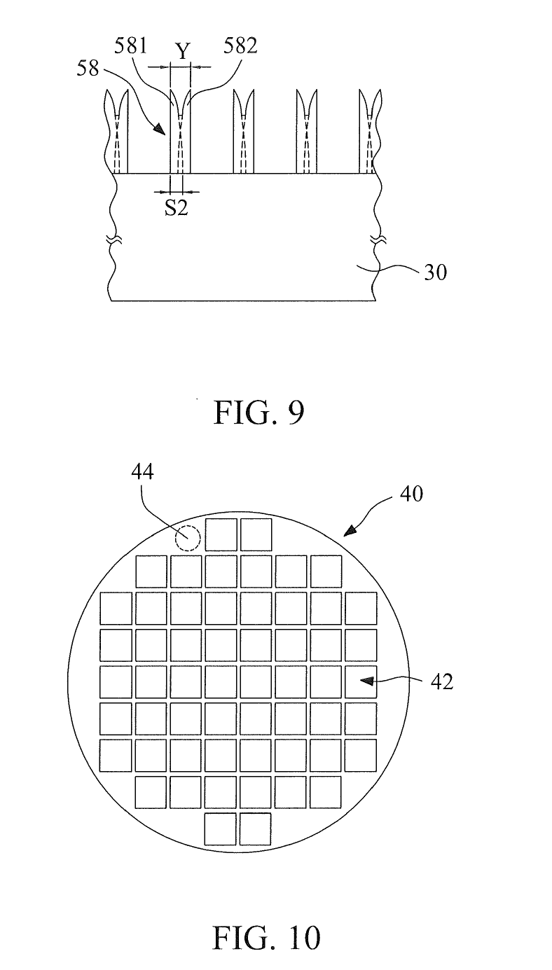

FIG. 7 is a top view showing a portion of an overlay mark according to one embodiment of the present invention. FIG. 8 is a cross-sectional side view along line 5-5 of FIG. 7 according to one embodiment of the present invention. FIG. 9 is a cross-sectional side view along line 6-6 of FIG. 7 according to one embodiment of the present invention. As shown in FIGS. 7 to 9, after the growth of the mark material 22, the patterned layer 10 is removed by using an etching solution, for example. The etching solution may be acetone, for example. Consequently, an overlay mark of the present invention is fabricated.

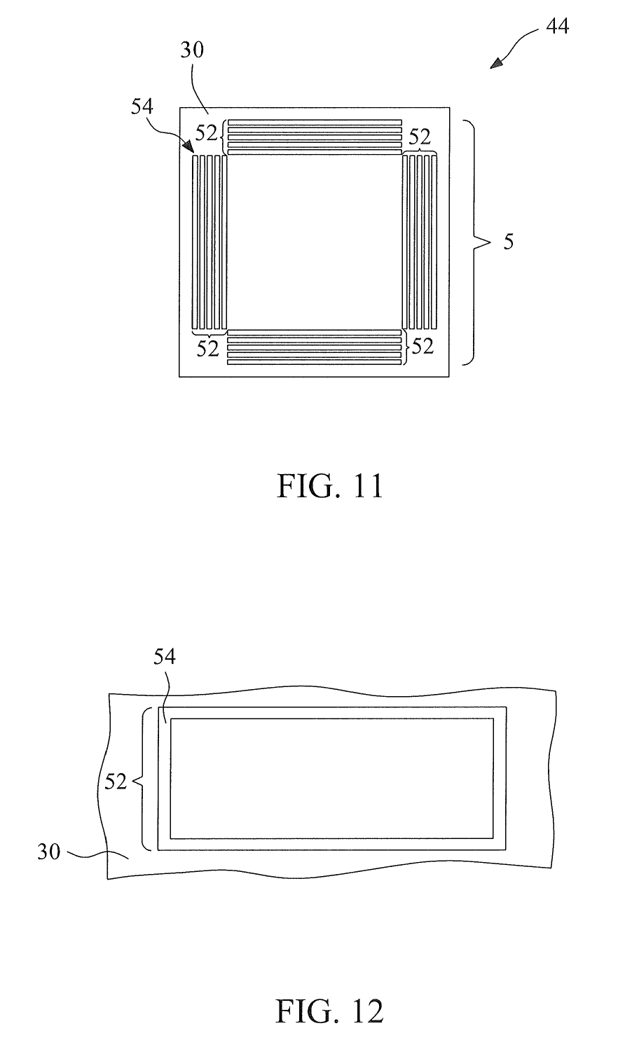

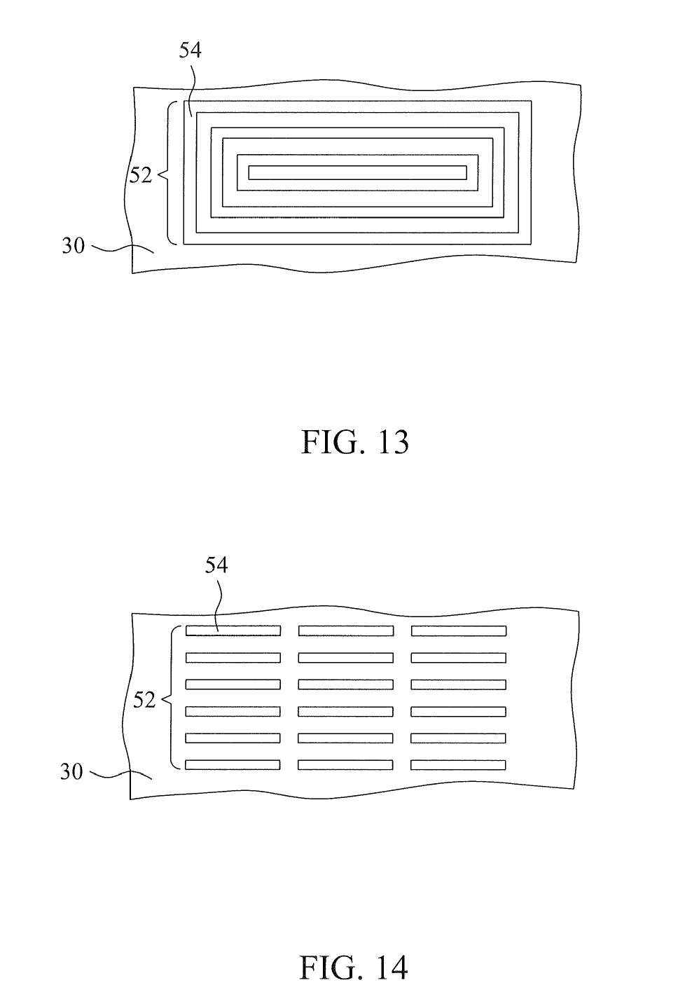

FIG. 10 is a top view showing a substrate 40 with a plurality of device regions thereon 42. FIG. 11 is a close-up top view showing an overlay mark 5 in an overlay alignment region 44 of the substrate 40 according to one embodiment of the present invention. In should be noted that FIG. 7 can be considered as a portion of FIG. 11. As shown in FIGS. 10 and 11, in order to achieve proper overlay alignment, the overlay mark 5 comprising a plurality of mark elements 54 is formed in the overlay alignment region 44 on the substrate 40 such as a wafer. In one embodiment of the present invention, the material of the mark elements 54 is made of silicon germanium (SiGe), silicon oxide, or silicon nitride. In addition to the aforementioned materials, other suitable materials for making the mark elements 54 are applicable. In one embodiment of the present invention, the overlay mark 5 comprises a plurality of mark regions 52, and each mark region 52 comprises a plurality of mark elements 54. In this embodiment, the mark elements 54 are arranged as shown in FIG. 11, while the mark elements 54 can be arranged as shown in FIG. 12, 13 or 14, but are not limited thereto.

Referring to FIGS. 7 to 9 again, each mark element 54 includes two column elements 56 and a plurality of row elements 58, and the row elements 58 connect the two column elements 56 to form a plurality of holes 60 exposing the substrate 30 between the two column elements 56. It should be noted that the holes 60 may be, but are not limited to, polygonal or circular shapes, or a combination thereof.

Each column element 56 has a width X less than twice the width 51 of a first spacer 561 or 562 (see FIG. 8), wherein each column element 56 is formed by two first spacers 561, 562 merging with each other. Each row element 58 has a width Y less than twice the width S2 of a second spacer 581 or 582 (see FIG. 9), wherein each row element 58 is formed by two second spacers 581, 582 merging with each other. The second spacer width S2 may be the same as or different from the first spacer width S1.

Since each mark element 54 of the overlay mark 5 of the present invention has a width greater than that of the conventional overlay mark, the overlay mark 5 of the present invention can have high image contrast. That is, for spacer double patterning processes, it is effective to use the overlay mark 5 of the present invention to monitor overlay performance, and for overlay measurement.

Although the present invention and its objectives have been described in detail, it should be understood that various changes, substitutions and alterations can be made herein without departing from the spirit and scope of the invention as defined by the appended claims. For example, many of the processes discussed above can be implemented using different methodologies, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An overlay mark on a substrate, comprising a plurality of mark elements, wherein each mark element includes two column elements and a plurality of row elements, and the row elements connect the two column elements to form a plurality of holes exposing the substrate between the two column elements.

2. The overlay mark of claim 1, wherein the overlay mark is formed on a silicon substrate.

3. The overlay mark of claim 1, wherein the overlay mark is made of silicon germanium (SiGe), silicon oxide, or silicon nitride.

4. The overlay mark of claim 1, wherein each column element is formed by two first spacers merging with each other.

5. The overlay mark of claim 4, wherein the first spacer has a width, and the column element has a width less than twice the width of the first spacer.

6. The overlay mark of claim 1, wherein each row element is formed by two second spacers merging with each other.

7. The overlay mark of claim 6, wherein the second spacer has a width, and the row element has a width less than twice the width of the second spacer.

8. The overlay mark of claim 1, wherein the hole is polygonal or circular in shape, or a combination thereof.

9. A method for fabricating an overlay mark, comprising the steps of:
forming a patterned layer on a substrate, wherein the patterned layer comprises at least one mark element forming region, wherein each mark element forming region comprises two column recesses and a plurality of row recesses, and the row recesses connect the two column recesses;
growing a mark material from sidewalls of the column recesses and the row recesses so that the mark material merges in the column recesses and the row recesses; and
removing the patterned layer.

10. The method of claim 9, wherein the patterned layer is a photoresist layer.

11. The method of claim 10, wherein the patterned layer is removed using an etching solution.

12. The method of claim 11, wherein the etching solution is acetone.

13. The method of claim 9, wherein the mark material is made of silicon germanium (SiGe), silicon oxide, or silicon nitride.

14. The method of claim 9, wherein the growing of the mark material comprises growing first spacers from the sidewalls of the column recesses and second spacers from the sidewalls of the row recesses.

15. The method of claim 14, wherein the first spacer has a width, and the column recess has a width less than twice the width of the first spacer.

16. The method of claim 14, wherein the second spacer has a width, and the row recess has a width less than twice the width of the second spacer.

17. The method of claim 9, wherein each mark element forming region further comprises a plurality of segments arranged between the column recesses and the row recesses and spaced from each other.

18. The method of claim 17, wherein the segment is polygonal or circular in shape, or a combination thereof.

19. The method of claim 9, wherein the mark material is formed by low temperature chemical vapor deposition (LTCVD).
